(19) United States
(12) Patent Application Publication
(10) Pub. No.: US 2014/0252309 A1
(43) Pub. Date: Sep. 11, 2014

(54) VISIBLE-LIGHT LIGHT EMITTING DIODE FOR HIGH-SPEED VEHICLE COMMUNICATION

(71) Applicant: NATIONAL CENTRAL UNIVERSITY, Taoyuan County (TW)

(72) Inventors: Jin-Wei Shi, Taipei City (TW); Jinn-Kong Sheu, Tainan County (TW); Kai-Lun Chi, New Taipei City (TW)

(73) Assignee: NATIONAL CENTRAL UNIVERSITY, Taoyuan County (TW)

(21) Appl. No.: 13/790,939

(22) Filed: Mar. 8, 2013

(51) Int. Cl. H01L 33/06

(52) U.S. Cl. CPC H01L 33/06
USPC 257/13

(57) ABSTRACT

A visible-light light emitting diode having a center wavelength of 400 to 560 nm formed on a patterned sapphire substrate and with a four-layer quantum well as an active layer. The patterned sapphire substrate can include a plurality of recesses having openings and a plurality of convex portions on one surface thereof, the recesses being integrally formed between the neighboring convex portions or a plurality of convex portions on one surface thereof, a recess being defined between two of the neighboring convex portions and wherein the convex portions on the surface are made of dielectric material. A lens layer is disposed on an upper P-type doped region.

### BACKGROUND OF THE INVENTION

1. Field of the Invention

The present invention relates to a very high-speed visible-light light emitting diode, and particularly to a visible-light light emitting diode for vehicle optical fiber communication. More particularly, it relates to a very high-speed visible-light light emitting diode which has a center wavelength of 400˜560 nm, can reach high speed, high efficiency and high performance, and can minimize the leakage current.

2. Description of Related Art

With the progress of science and technology, the plastic optical fiber applications have been made more widely, not only to the motherboard but also the mobile phone. The speed increases up to 500 Mbps in connection bandwidth or 1 Gbps in backplane bandwidth. It can replace the vast majority of high-tech consumer goods which need to use glass fibers. Currently, a Toslink plastic optical fiber transmission module is mainly used in the audio field due to the limited transmission speed. When the speed increases up to 1 Gbps, the transmission of the image can be also applied to other fields, such as high-definition television which has been developing, signal transmission for automobile driving instant images, data upload and download for digital camera, or infrastructure for transmission medium of home network by means of IEEE-1394 architecture and plastic optical fibers.

FIG. 5 is a schematic view of a conventional vehicle plastic optical fiber communication system. FIG. 6 is a schematic diagram of PMMA optical fiber loss vs. wavelength spectrum. As shown, the current plastic optical fiber main market is the applications in vehicle optical fiber communication. Automobile Industry Alliance (MOST) has been drawn up its specifications. The specifications include a high-speed red diode of 22.5 million bits/second (Mbit/sec) and a PMMA plastic optical fiber 5.

However PMMA optical fiber, as shown in FIG. 6, actually has the lowest loss window at 520 nm and 570 nm bands. The window at wavelengths of 650 nm has the loss of about 125 db per kilometer (125 dB/km) Compared to the windows at 520 nm and 570 nm, it not only has higher loss but also narrower band, and results in some problems. For example, when laser diodes or light-emitting diode is used as the light source and operated for long time, light source wavelength offset may occur because of the effect of prolonged heat so that the light source has to be operated at the band which may cause larger loss and accordingly more optical power loss.

For the red RCLED, power and output wavelength are extremely sensitive to the changes in ambient temperature. The change in temperature will lead to the operating wavelength of the red RCLED out of the red-light operating window of PMMA plastic optical fiber.

In summary, since the high-speed red light-emitting diode used for the traditional vehicle plastic optical fiber communication needs to grow a complex cavity epitaxial layer, which not only has great loss in optical power, but also the conflict between the speed and power in devices easily causes the deterioration of coupling efficiency for the light source and the optical fiber. Therefore, the prior art cannot meet the need for the users in actual use.

### SUMMARY OF THE INVENTION

A main purpose of this invention is to provide a visible-light light emitting diode which can solve the above problems and use a patterned sapphire substrate as the light source of plastic optical fiber communication. By reducing the number of quantum wells in the active layer and narrowing the light emitting area and integrating a metal package and a lens, high speed, high efficiency and high performance can be reached and the leakage current can be minimized as well.

In order to achieve the above and other objectives, the visible-light light emitting diode for high-speed vehicle communication includes a patterned substrate, having an undulated surface; an N-type doped region, provided on the patterned substrate; an active layer, disposed on the N-type doped region and comprising a barrier layer and a multiple quantum well (MQW) with a four-layer quantum well; a P-type doped region, disposed on the active layer; and a lens layer, disposed on the P-type doped region.

In one of preferred embodiments, the patterned substrate is a patterned sapphire substrate (PSS).

In one of preferred embodiments, the patterned substrate has a plurality of recesses having openings and a plurality of convex portions on one surface thereof, the recesses being integrally formed between the neighboring convex portions.

In one of preferred embodiments, the patterned substrate has a plurality of convex portions on one surface thereof, a recess being defined between two of the neighboring convex portions.

In one of preferred embodiments, the convex portions on the surface are made of dielectric material.

In one of preferred embodiments, the lens layer is disposed on the P-type doped region by means of an adhesive layer.

In one of preferred embodiments, the adhesive layer is UV glue

In one of preferred embodiments, a center wavelength of the visible-light light emitting diode is 400˜560 nm.

### BRIEF DESCRIPTION OF THE DRAWINGS

FIG. 1A is a schematic, cross-sectional view of a visible-light light emitting diode according to one embodiment of the invention.

FIG. 1B is a schematic, cross-sectional view of a visible-light light emitting diode according to another embodiment of the invention.

FIG. 2 is a schematic view showing the relationship between optical power of the optical fiber coupling and the bias current of LED with and without lens according to the invention.

FIG. 3 is a schematic diagram of E-O modulation frequency responses of LED package with and without lens obtained at different bias currents according to the invention.

FIG. 4 is a schematic eye diagram of LED bias current with and without lens at 40 Ma according to the present invention.

FIG. 5 is a schematic view of a conventional vehicle plastic optical fiber communication system.

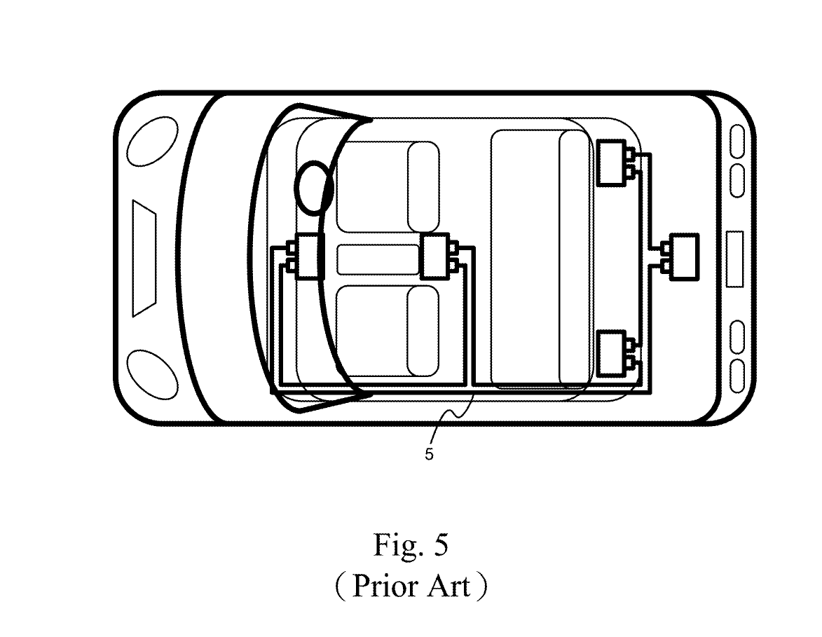

FIG. 6 is a schematic diagram of PMMA optical fiber loss vs. wavelength spectrum.

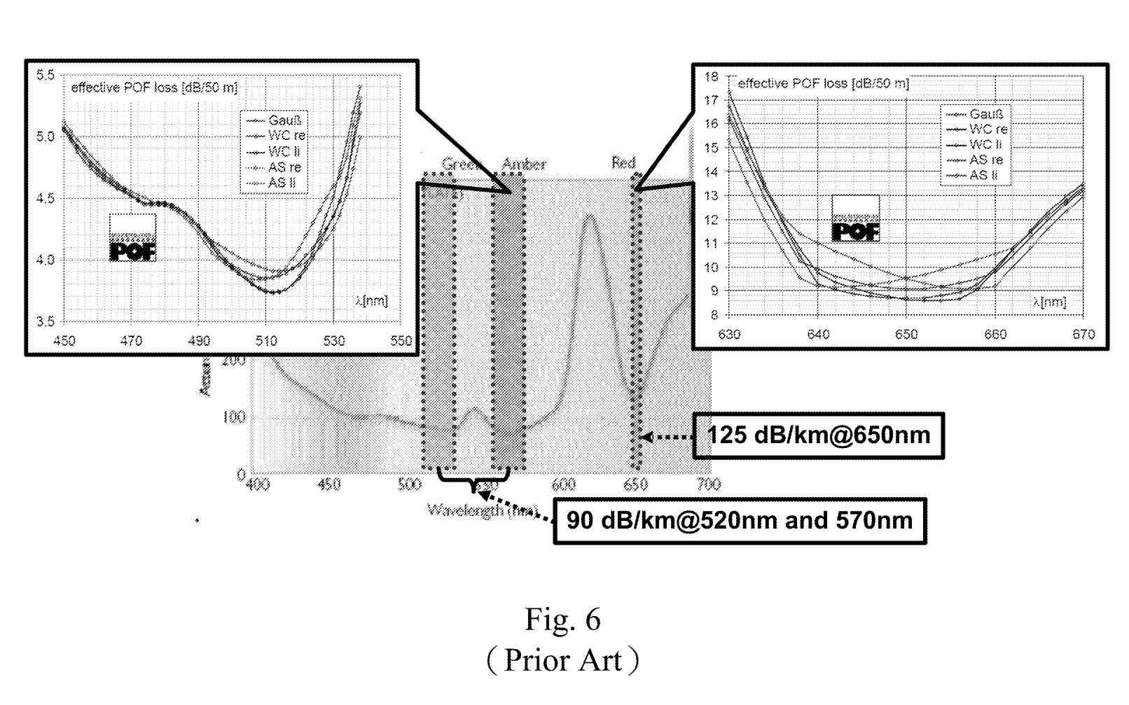

### DETAILED DESCRIPTION OF THE PREFERRED EMBODIMENTS

The aforementioned illustrations and following detailed descriptions are exemplary for the purpose of further explaining the scope of the present invention. Other objectives and advantages related to the present invention will be illustrated in the subsequent descriptions and appended tables.

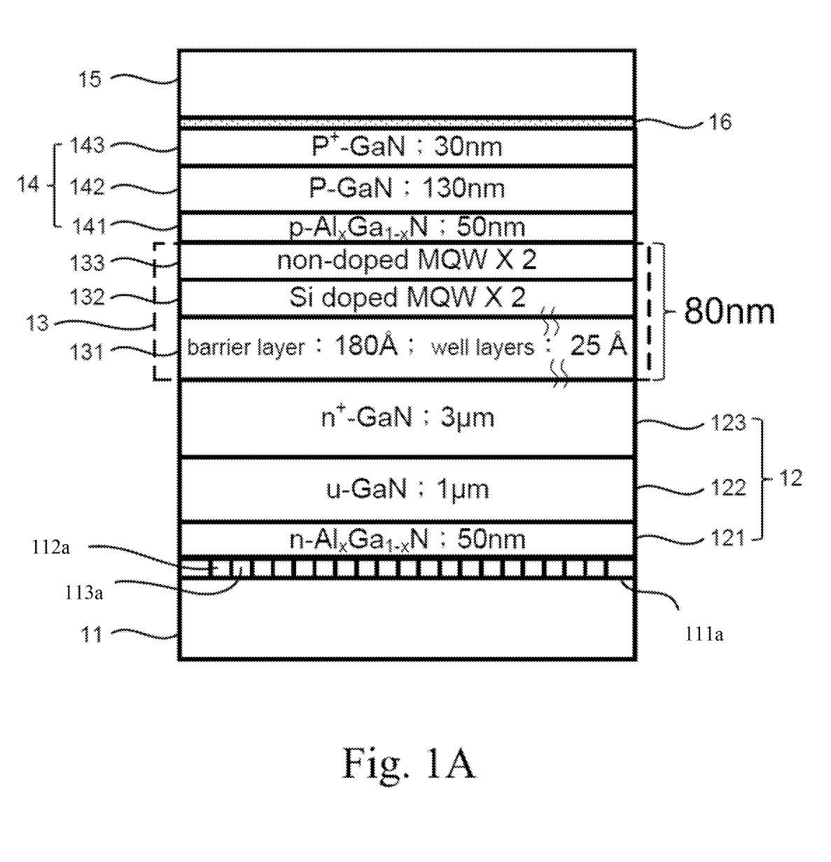

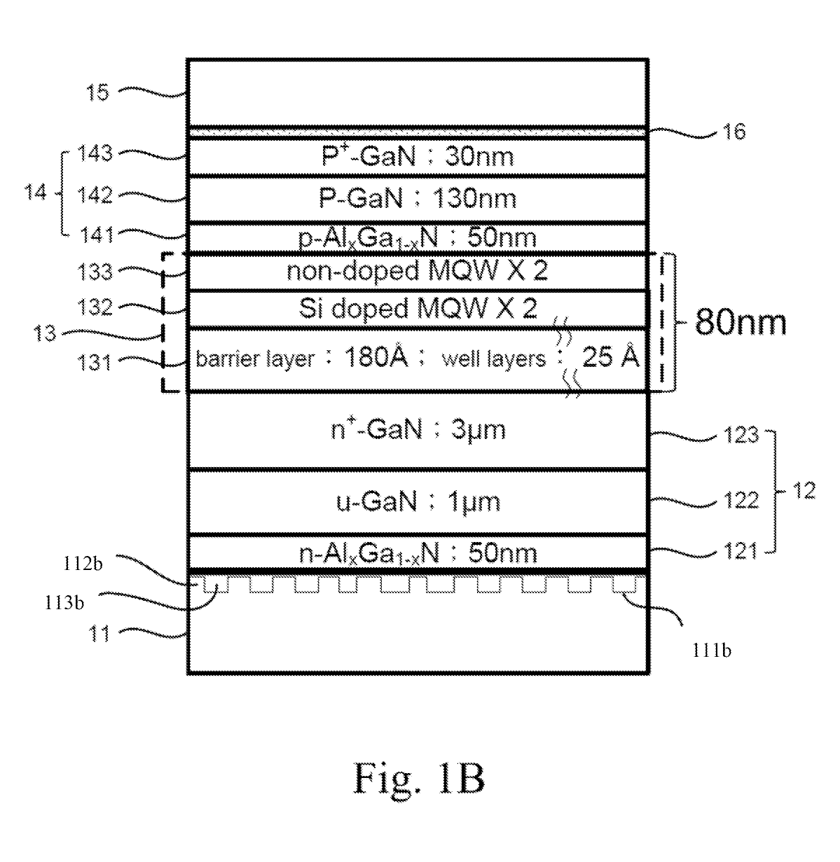

FIG. 1A is a schematic, cross-sectional view of a visible-light light emitting diode according to one embodiment of the invention. FIG. 1B is a schematic, cross-sectional view of a visible-light light emitting diode according to another embodiment of the invention. As shown, the visible-light light emitting diode for high-speed vehicle communication according to the present invention includes a patterned substrate 11, an N-type doped region 12, an active layer 13, a P-type doped region 14 and a lens layer 15.

The patterned substrate 11 can be a patterned sapphire substrate (PSS), and have an undulated surface. In one specific embodiment, as shown in FIG. 1A, the patterned substrate 11 has a plurality of convex portions 112a formed on a surface 111a. A recess 113a is defined between two of the neighboring convex portions 112a which are next to each other. The convex portions 112a on the surface 111a can be made of dielectric material. In another particular embodiment, such as shown in FIG. 1B, a surface 111b of the patterned substrate 11 includes a plurality of recesses 113b having openings. The recesses 113b are integrally formed between the neighboring convex portions 112b on the surface 111b.

The N-type doped region 12 is provided on the patterned substrate 11, and includes an N-type nitride aluminum (n-AlN) layer 121 having a thickness of 50 nm, a non-doped gallium nitride (u-GaN) layer 122 having a thickness of 1 μm, and an N-type gallium nitride (n⁺-GaN) layer 123 having a thickness of 3 μm.

The active layer 13 is disposed on the N-type doped region 12, and consists of a barrier layer 131 and a multiple quantum well (MQW) with a four-layer quantum well. The total thickness of the active layer can be 80 nm. The barrier layer 131 has a thickness of 180 angstroms (Å). The four-layer quantum well contains two silicon-doped quantum well doped layers 132, and two non-doped quantum well layers 133. These well layers have the thickness of 25 Å in total.

The P-type doped region 14 provided on the active layer 13, and contains a P-type aluminum gallium nitride (p-AlₓGa₁₋ₓN) layer 141 having a thickness of 50 nm, a P-type gallium nitride (p GaN) layer 142 having a thickness of 130 nm, and a P-type gallium nitride (p⁺-GaN) layer 143 having a thickness of 30 nm.

The lens layer 15 is disposed on the P-type doped region 14. Between the lens layer 15 and the P-type doped region 14 is sandwiched an adhesive layer 16 for the lens layer 15 to adhere onto the P-type doped region 14. The adhesion layer 16 may be UV glue. As such, a novel visible-light light emitting diode for high-speed vehicle communication is completed.

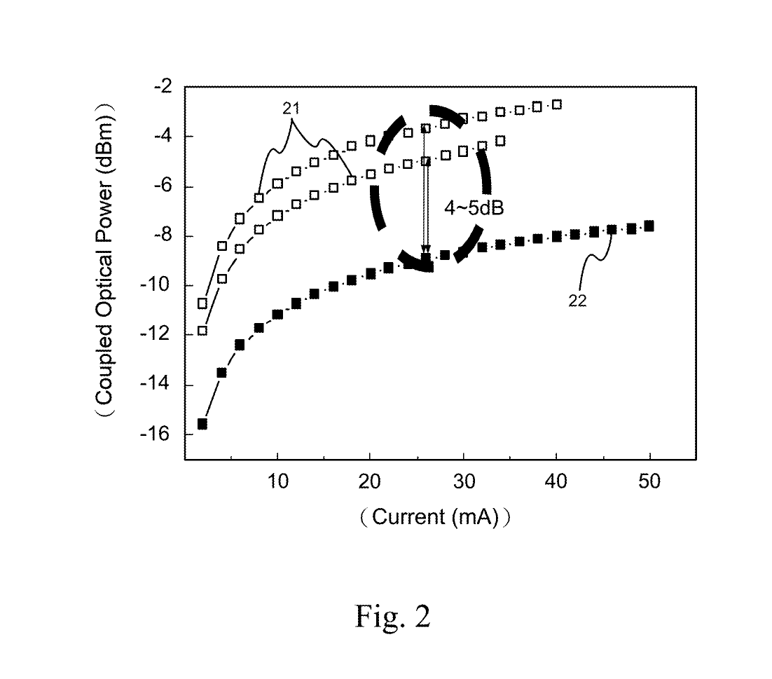

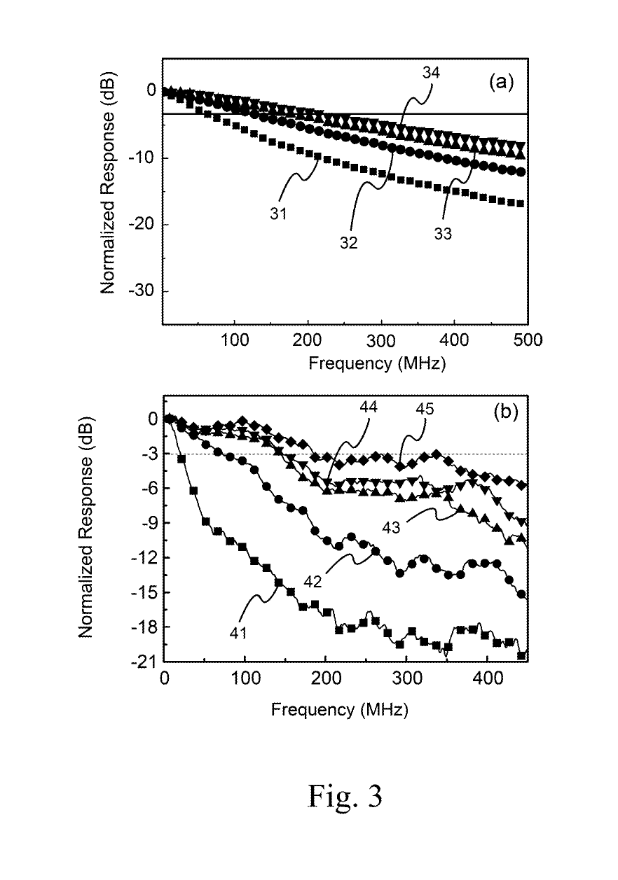

FIG. 2 is a schematic view showing the relationship between optical power of the optical fiber coupling and the bias current of LED with and without lens according to the invention. FIG. 3 is a schematic diagram of E-O modulation frequency responses of LED package with and without lens obtained at different bias currents according to the invention. As shown in FIG. 2, PI curves 21, 22 in the white/black blocks respectively represent the optical fiber coupling power for LEDs, with and without lens, obtained by using lm plastic optical fiber in the shape of integrated sphere. The results show that the two PI curves measured by the use of two different types of packaging devices 21, 22, respectively, represent the best and worst measurement results. Compared with the solution of the direct coupling (i.e., without lens), the coupling with lens can offer better coupling efficiency about 4˜5 dB than the coupling without lens. Accordingly, during the test, the maximal optical fiber coupling power of −2.67 dBm is obtained at bias current of 40 mA. This is about 36% of the whole available power for the apparatus. The above results show that the visible-light light emitting diode of the invention is comparable with the commercially available red light resonant cavity light emitting diode (Red RCLED) which is designed for data transmission at 250-Mb/s and optical fiber coupling power of −2 dBm at bias current of 45 mA. For the invention, the same power of Red RCLED can be reached by using a low current, and higher speed than Red RCLED and smaller area can be further obtained.

Furthermore, FIG. 3(a) shows electro-optic modulation frequency responses of the packaging unit (containing the lens) with a luminous area having a diameter of 75 μm. The curve 31 represents the frequency responses obtained at bias current of 10 mA. The curve 32 represents the frequency responses obtained at bias current of 20 mA. The curve 33 represents the frequency responses obtained at bias current of 30 mA. The curve 34 represents the frequency responses obtained at bias current of 40 mA. FIG. 3(b) shows electro-optic modulation frequency responses of the packaging unit (containing no lens) with a luminous area having a diameter of 75 μm. The curve 41 represents the frequency responses obtained at bias current of 1 mA. The curve 42 represents the frequency responses obtained at bias current of 10 mA. The curve 43 represents the frequency responses obtained at bias current of 30 mA. The curve 44 represents the frequency responses obtained at bias current of 40 mA. The curve 45 represents the frequency responses obtained at bias current of 60 mA. It is found that the result obtained at 3 dB bandwidth is about 210 MHz, i.e., close to the result of FIG. 3(b) according to the wafer level measurement. The measured maximal speed performance for the small device of the present invention is better than the traditional high-speed (350 MHz) red RCLED.

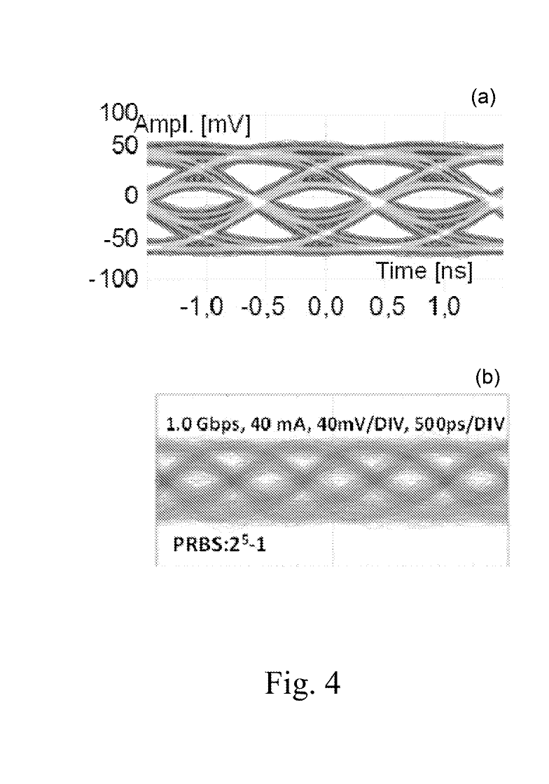

FIG. 4 is a schematic eye diagram of LED bias current with and without lens at 40 Ma according to the present invention. As shown, it needs higher optical fiber coupling efficiency to improve the system performance Therefore, the present invention measures the transmission links for 10 m steP-type plastic optical fiber (SI-POF) at bias current of 40 mA to obtain 1-Gb/s eye-diagram, with the use of 75 μm LED containing the lens. The measurement result show that the device may be operated at 40 mA to make the eye diagram open, in which the eyes width becomes significantly larger. It is obvious that the higher optical power can be offered remote from the system by means of improving the coupling efficiency of LED. Thereby, the invention can get the eye diagram of 1-Gb/s. As shown in FIG. 4(a), it is found that better noise ratio than FIG. 4(b) can be obtained at the same data rate and bias current (40 mA).

Thus, the present invention proposes a novel visible-light light emitting diode which has a center wavelength of 400˜560 nm. By using a patterned sapphire substrate as the light source of the plastic optical fiber communication, it can provide this high-speed light emitting diode of very small dimension with increased external quantum efficiency and output power, achieving high-speed and high-power performance By reducing the number of quantum wells in the active layer InₓGa₁₋ₓN/GaN and narrowing the light emitting area, a very high-speed electro-optical conversion bandwidth (up to 400 MHz) can be obtained in all high-speed visible-light light emitting diodes with the use of very small DC bias current (40 mA). The integration of a metal package TO-can (Transistor Out-line can) and a lens with diameter of 75 μm contributes to the increase of about 4˜5 dB when the plastic optical fiber is used instead of the chip. In addition, the power can be up to −2.67 dBm at bias current of 40 mA.

In summary, the present invention relates to a visible-light light emitting diode for high-speed vehicle communication which can effectively improve the shortcomings of prior art. The patterned sapphire substrate is used as the light source of the plastic optical fiber communication to increase the external quantum efficiency and output power for the high-speed light emitting diode with extremely small size, achieving the high-speed, high-power performance By reducing the number of quantum wells in the active layer and narrowing the light emitting area of the device, a very high-speed conversion of electro-optic bandwidth can be obtained for all high-speed visible-light light emitting diode. The current modulation efficiency can be reached by only using a very small DC bias current. Finally, the output power of data transmission for the LED can be effectively improved and the leakage current can be minimized through the integration of a lens a, and finally through the integration of a lens. This makes the invention more progressive and more practical in use which complies with the patent law.

The descriptions illustrated supra set forth simply the preferred embodiments of the present invention; however, the characteristics of the present invention are by no means restricted thereto. All changes, alternations, or modifications conveniently considered by those skilled in the art are deemed to be encompassed within the scope of the present invention delineated by the following claims.

1. A visible-light light emitting diode for high-speed vehicle communication, comprising
a patterned sapphire substrate, having an undulated surface;
an N-type doped region, provided on the patterned substrate;
an active layer, disposed on the N-type doped region and comprising a barrier layer and a multiple quantum well (MQW) with a four-layer quantum well;
a P-type doped region, disposed on the active layer; and
a lens layer, disposed on the P-type doped region.

2. (canceled)

3. The visible-light light emitting diode of claim 1, wherein the patterned substrate has a plurality of recesses having openings and a plurality of convex portions on one surface thereof, the recesses being integrally formed between the neighboring convex portions.

4. The visible-light light emitting diode of claim 1, wherein the patterned substrate has a plurality of convex portions on one surface thereof, a recess being defined between two of the neighboring convex portions.

5. The visible-light light emitting diode of claim 4, wherein the convex portions on the surface are made of dielectric material.

6. The visible-light light emitting diode of claim 1, wherein the lens layer is disposed on the P-type doped region by means of an adhesive layer.

7. The visible-light light emitting diode of claim 6, wherein the adhesive layer is UV glue.

8. The visible-light light emitting diode of claim 1, wherein a center wavelength of the visible-light light emitting diode is 400 to 560 nm.

9. The visible-light light emitting diode of claim 1, wherein the N-type doped region includes an N-type aluminum gallium nitride (n-AlₓGa₁₋ₓN) layer, a non-doped gallium nitride (u-GaN) layer, and an N-type gallium nitride (n⁺-GaN) layer.

10. The visible-light light emitting diode of claim 1, wherein the P-type doped region includes a P-type aluminum gallium nitride (p-AlₓGa₁₋ₓN) layer, a P-type gallium nitride (p-GaN) layer, and a P-type gallium nitride (p⁺-GaN) layer.
